(19) United States
(12) Patent Application Publication
(10) Pub. No.: US 2014/0303916 A1
(43) Pub. Date: Oct. 9, 2014

(54) FOUR-LINE ELECTRICAL IMPEDANCE PROBE

(71) Applicant: Brigham Young University, Provo, UT (US)

(72) Inventors: Brian Anthony Mazzeo, Provo, UT (US); Dean R. Wheeler, Orem, UT (US)

(73) Assignee: Brigham Young University, Provo, UT (US)

(21) Appl. No.: 14/246,007

(22) Filed: Apr. 4, 2014

Related U.S. Application Data
(60) Provisional application No. 61/853,446, filed on Apr. 4, 2013.
(60) Provisional application No. 61/896,560, filed on Oct. 28, 2013.

(51) Int. Cl. G01R 27/14; G01R 1/073

(52) U.S. Cl. CPC G01R 27/14; G01R 1/073
USPC 702/65; 324/149

(57) ABSTRACT

A probe is configured for measuring an electrical impedance of a workpiece using external testing equipment. The probe includes a non-conducting base and an array of at least four spaced-apart line conductors. The at least four spaced-apart line conductors are disposed generally in parallel to each other along their lengths on a surface of the non-conducting base and are electrically connected to a corresponding array of at least four terminals on the non-conducting base. The non-conducting base is configured to be placed over a surface of the workpiece so that the at least four spaced-apart line conductors contact the surface of the workpiece and the at least four terminals are configured to be connected the external testing equipment.

### CROSS-REFERENCE TO RELATED APPLICATIONS

This application claims priority to and the benefit of U.S. Provisional Patent Application No. 61/853,446 filed Apr. 4, 2013, and priority to and the benefit of U.S. Provisional Patent Application No. 61/896,560 filed Oct. 28, 2013, both of which are incorporated by reference herein in their entireties for all purposes.

### STATEMENT REGARDING FEDERALLY SPONSORED RESEARCH

This invention was made with government support under a grant awarded by the United States Department of Energy Office of Vehicle Technologies, Contract No. DE-AC02-05CH11231. The government has certain rights in the invention.

### TECHNICAL FIELD

This disclosure relates to devices and methods for measuring electrical impedances of materials including thin film materials.

### BACKGROUND

A four-point probe is a device that has two separate pairs of current-carrying and voltage-sensing metal point electrodes to measure the electrical impedances of materials. The current-carrying and voltage-sensing electrodes, which are needle-like and have metal tips. The metal tips are designed to make point contacts with a surface of a sample under test. Four-point probes may, for example, be used to measure the sheet resistance and bulk (volume) resistivity of materials.

Conventional four-point probe theory, which is used to compute the electrical impedances of the sample under test based on measured voltages and currents, assumes that the metal tips of the four-point probe are infinitesimal and the sample is semi-infinite in lateral dimension. The electrical impedance measurements made with a four-point probe are sensitive to the surface topography and characteristics of the sample material. Consideration is now being given to devices and methods for measuring the electrical impedances of diverse materials including inhomogeneous materials and materials having poor surface conditions for making consistent point contacts for electrical impedance measurements.

### BRIEF SUMMARY

In a general aspect, a probe for measuring electrical impedances of a material includes a base, and a plurality of line conductors aligned generally in parallel to each other on a surface of the base and electrically connected to a corresponding plurality of terminals on the base. The plurality of line conductors includes at least four line conductors. The base of the probe is configured to be placed over a surface of a workpiece so that the plurality of line conductors contact the surface of the workpiece, and the corresponding plurality of terminals are configured to be connected to external testing equipment.

The details of one or more implementations are set forth in the accompanying drawings and the description below. Other features will be apparent from the description and drawings, and from the claims.

### BRIEF DESCRIPTION OF THE DRAWINGS

FIGS. 1A and 1B are schematic illustrations of an example device (e.g., a micro four-line probe) that may be deployed to measure electrical impedance parameters of a workpiece or sample (e.g., battery electrode material), in accordance of the principles of the disclosure herein.

FIGS. 2A and 2B are schematic illustrations of an example micro four-line probe, which may be fabricated on a non-conducting base (e.g., a fused silica substrate), in accordance with the principles of the present disclosure.

FIG. 3 is a schematic illustration of a process for fabricating a micro four-line probe designed for measuring an electrical impedance of a workpiece, in accordance with the principles of the present disclosure.

FIG. 4 illustrates an example micro four-line probe fabricated using the process of FIG. 3, in accordance with the principles of the present disclosure.

FIG. 5 shows an example probe station, which may be used to measure electrical impedances of a sample at controlled locations and under controlled contact pressure using the probe of FIG. 4, in accordance with the principles of the present disclosure.

FIG. 6A illustrates an example two dimensional simulation of current flows in a sample during electrical impedance measurement using the probe of FIG. 4, in accordance with the principles of the present disclosure.

FIG. 6B illustrates an example two dimensional simulation of current flows in a sample during electrical impedance measurements, in accordance with the principles of the present disclosure.

FIG. 7 is a simulated plot of the apparent resistance Rapp-std of a material layer measured using the probe of FIG. 4 as a function of material layer thickness, in accordance with the principles of the present disclosure.

FIG. 8 is a logarithmic plot illustrating a qualitative dependence of a geometric shape factor S0 on probe contact resistance and collector layer contact resistance, in accordance with the principles of the present disclosure.

FIG. 9 is a flow chart illustrating an example method for determining electrical impedance parameters of a workpiece, in accordance with the principles of the disclosure herein.

Like reference symbols in the various drawings indicate like elements.

### DETAILED DESCRIPTION

Devices and methods for measuring electrical impedance parameters of diverse materials are disclosed herein. The materials may include spatially inhomogeneous materials or materials that have surfaces that are unsuitable for making consistent or reproducible point contact measurements because of surface roughness, porosity, granularity or compositional inhomogeneities, which may, for example, be on a scale of about 5 μm. In some implementations, the scale can be less than 5 μm or greater than 5 μm.

An example material, which may not be amenable to accurate or consistent electrical impedance characterization by a traditional four-point probe, is the composite material that is used, for example, in battery electrodes (e.g., lithium-ion batteries). Lithium-ion battery electrodes are typically composed of a metal oxide active material, carbon, and binder such as polyvinylidene fluoride (PVDF) that are mixed together in a slurry. In a continuous coating process used for commercial production of the battery electrodes, the slurry is cast as a material layer on to a thin aluminum “current collector” using a doctor blade to control deposition thickness. However, it is difficult to maintain uniform properties of the material layer used in the continuous coating process; as a result commercially produced battery electrode materials have variable electronic and ionic properties. Because of surface roughness and compositional variations in the battery electrode material, four-point probe measurements may not be accurate or useful in electrical impedance characterization of the battery electrode material, for example, for process quality control.

Furthermore, accurate measurement of the electrical impedance of a material of interest may be difficult or inaccurate when the material of interest is attached to one or more additional materials having different electrical impedance properties. For example, a battery electrode semi-conducting film is commonly attached to a highly conductive metallic current collector, which makes it difficult to measure the electrical impedance of the semi-conducting film independent of the electrical impedance of the attached highly conductive metallic current collector. Additionally, accurate measurement of electrical impedances of inhomogeneous and porous materials may be difficult when an external force or pressure applied to the material of interest during the measurement is unknown or not well-controlled. This is because electrical impedances of the materials can be substantially altered by external pressure.

In accordance with the principles of the disclosure herein, devices for measuring the electrical impedance parameters (e.g., bulk conductivity or resistivity, permittivity, contact impedance, etc.) may utilize line conductors to make electrical contact over large or macroscopic areas of a surface of a material under test. The macroscopic contact areas may have dimensions (e.g., ˜1000 sq. μm) that are large compared to the scale (e.g., ˜5 μm) of structural or compositional variations in the surface of a material under test. Making an electrical contact over a macroscopic area may smooth out spatial variations, for example, due to material inhomogeneities or surface roughness, and provide accurate or truly representative values of the electrical impedance parameters (e.g., bulk conductivity or resistivity, contact resistance, permittivity, contact impedance, etc.) of the material under test.

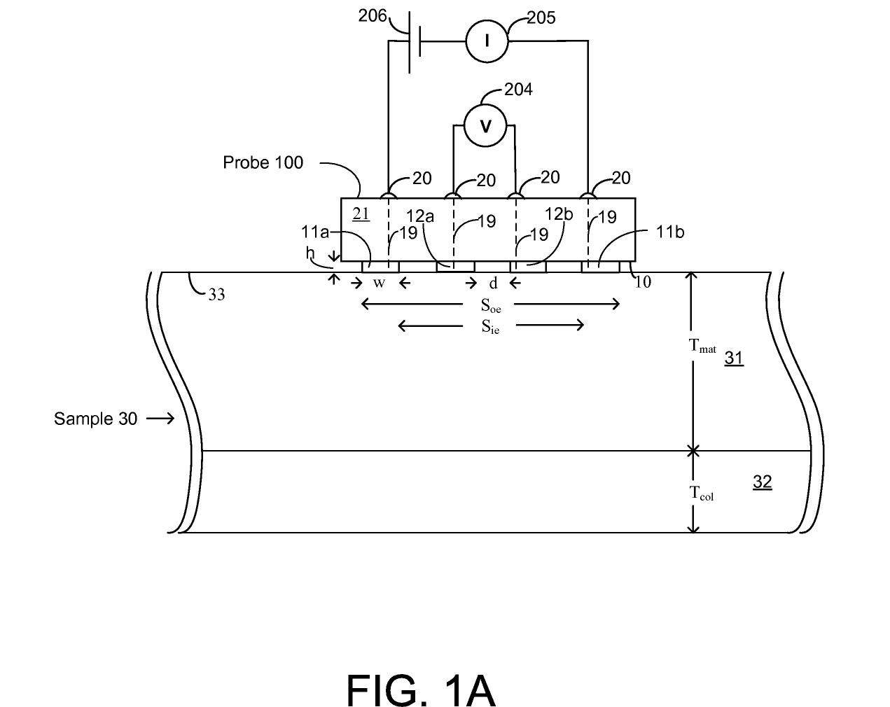

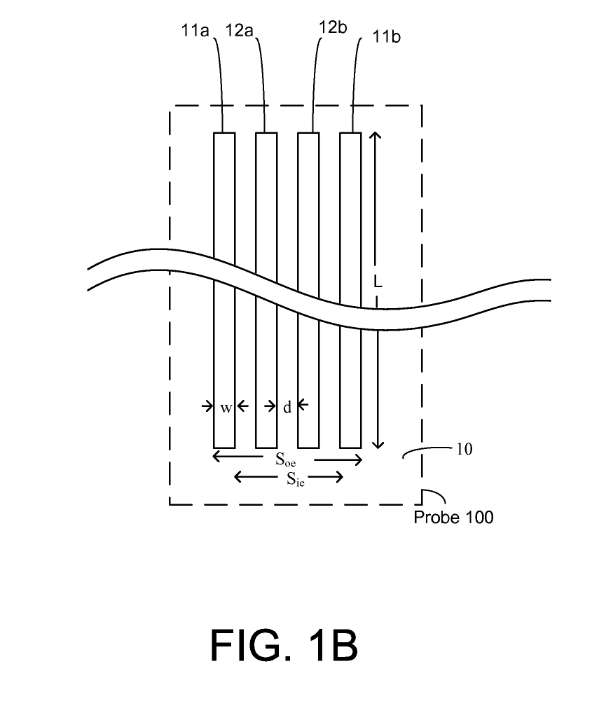

FIGS. 1A and 1B show schematic views of a micro four-line probe 100 that may be deployed to measure electrical impedance parameters of a workpiece or sample 30 (e.g., battery electrode material), in accordance of the principles of the disclosure herein. In particular, FIG. 1A shows a cross sectional view of probe 100 as deployed to measure the electrical impedances of sample 30. FIG. 1B shows a schematic plan view of an exploded surface portion of probe 100. As shown in FIG. 1A, sample 30 that may be used as a workpiece for electrical impedance measurements using probe 100 may, for example, be a sample of battery electrode material including a material layer 31 which is coated on a current collector layer 32 (e.g., a metal or conductive support layer).

Probe 100 includes four line conductors 11a, 11b, 12a, and 12b supported on a base 21. Line conductors 11a, 11b, 12a, and 12b, which may be lithographically patterned, may include metal deposited or electroplated on a surface 10 of base 21. Each of line conductors 11a, 11b, 12a, and 12b may have a length L on the order of a few mm (e.g., ˜10 mm), and a width w on the order of a few microns (e.g., ˜10 μm) along surface 10. The lengths L of line conductors 11a, 11b, 12a, and 12b may be substantially greater (e.g., 50 times, 100 times, 1000 times, etc.) than their widths w. Line conductors 11a, 11b, 12a, and 12b may be generally disposed in parallel to each other along their lengths L on surface 10 and separated from each other by an inter-line spacing d (which can be the same (e.g., constant) or can be different between the line conductors) along surface 10 in the direction of their widths. The outermost pair of the line conductors (e.g., 11a and 11b) may have an outer edge-to-outer edge separation Sₒₑ (or an inner edge-to-inner edge separation Sᵢₑ) as shown in FIGS. 1A and 1B. Further, each line conductor 11a, 11b, 12a, and 12b may extend or protrude vertically to a height (h) (e.g., ˜0.1 to 1 μm) above surface 10 as shown in FIG. 1A.

Further, line conductors 11a, 11b, 12a, and 12b, may be electrically connected to terminals 20 on base 21 via electrically conductive paths 19 passing through (e.g., coupled through) base 21. Terminals 20 may be configured to be connected to external testing equipment (e.g., power supplies, current sources, battery 206, ammeter 205, voltmeter 204, digital multimeters, signal analyzers, processors, controllers, etc.) (not all shown) may be utilized to measure or apply currents and voltages to sample 30 through line conductors 11a, 11b, 12a, and 12b for electrical impedance measurements of sample 30.

As shown in FIG. 1A, probe 100 may be configured so that when it is placed on sample 30 for measuring the electrical impedance, for example, of material layer 31, line conductors 11a, 11b, 12a, and 12b engage and electrically contact a surface (e.g., a top surface 33) of sample 30 under test.

An electrical impedance measurement using probe 100 may be based, for example, on Ohm's law R=V/I. As part of the electrical impedance measurement, external testing equipment connected to terminals 20 (e.g., voltmeter 204, ammeter 205, battery 206) may, for example, be utilized to inject and measure a current (I) flowing into sample 30 via an outer pair of line conductors (e.g., line conductors 11a and 11b) and to measure a voltage (V) developed across a portion of material layer 31 between an inner pair of line conductors (e.g., 12a and 12b). An impedance R may be determined by taking a ratio of the measured voltage V and the injected current I. If the injected current I is time-varying, the measured voltage V may also be time-varying and the resistance R, which is determined by taking the ratio of the measured voltage and injected current, may be a complex impedance that includes the effect of time-varying current and voltage.

In the example shown in FIG. 1A, the outer pair of line conductors 11a and 11b may serve as a pair of force conductors to establish a current flow through material layer 31, and the inner pair of line conductors 12a and 12b may serve as a pair of sense conductors to measure a voltage developed across a portion of material layer 31 therebetween.

The lengths L of line conductors 11a, 11b, 12a, and 12b in probe 100 may be considerably larger than their widths (w) or heights (h) (e.g., by a factor of, for example, 50 times, 100 times, 1000 times, etc.) so that the current and voltage distributions in the volume of sample 30 created by injecting current or applying voltages to line conductors 11a, 11b, 12a, and 12b may be substantially independent of position along the lengths of line conductors 11a, 11b, 12a, and 12b. The contribution of the ends of line conductors 11a, 11b, 12a, and 12b to the current or voltage distributions in the volume of sample 30 may be negligible. The current and voltage distributions in sample 30 (neglecting line conductor end effects) may be effectively represented by two-dimensional current and voltage distributions in any two-dimensional plane in sample 30 perpendicular to the lengths of line conductors 11a, 11 b, 12a, and 12b. Such two-dimensional representation may simplify analysis of the electrical impedance measurements of sample 30 using probe 100.

In probe 100, base 21 may be made, for example, of a planar insulating material (e.g., a rigid plastic or polymer sheet, a semiconductor wafer, a quartz or fused silica substrate). Line conductors 11a, 11b, 12a, and 12b in probe 100 may be fabricated on non-conducting base 21 using, for example, traditional micro fabrication or printed board circuit manufacturing techniques.

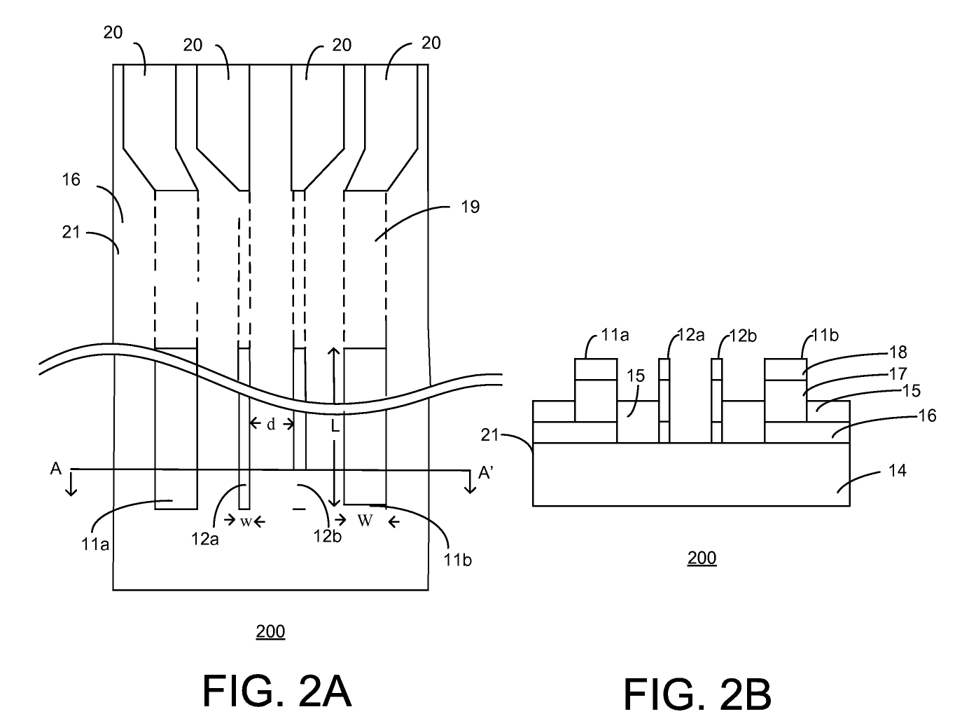

FIGS. 2A and 2B show views of an example probe 200, which may be fabricated on base 21 in accordance with the principles of the present disclosure. Base 21 may, for example, include an insulating substrate (e.g., a fused silica substrate 14) and further include different optional insulating layers or coatings of different thicknesses on the insulating substrate. In the example shown in FIGS. 2A and 2B, base 21 may include fused silica substrate 14 and an insulating polymer coating 15. Line conductors 11a, 11 b, 12a, and 12b supported on fused silica substrate 14 may be formed as a stack of deposited or electroplated metal layers 16, 17 and 18 (e.g., nickel, copper and gold, respectively) (as shown in FIG. 2B). Nickel layer 16 may also serve to form conductive paths 19 through base 21 and terminals 20 as exposed nickel pads at the edges of base 21 (as shown in FIG. 2A). It may be noted that in probe 200, line conductors 11a, 11b, 12a, and 12b may have the same or different widths and inter-line conductor spacings d. For example, as shown in the figure, line conductors 11a and 11b may each have a width W and line conductors 12a and 12b may each have a different width w, which is less than W. However, each of line conductors 11a, 11 b, 12a, and 12b may have a length L that is substantially larger than their width (W or w). Further, while the example shown in the figure represents the case where the inter-line conductor spacings d are substantially the same, other implementations may have varied inter-conductor spacings d. Insulating polymer coating 15 (or other insulating material (not shown)) may optionally extend or cover substrate 14 in the inter-line conductor spacing d between a pair, a select few pairs, or all pairs of line conductors 11a, 11b, 12a, and 12b.

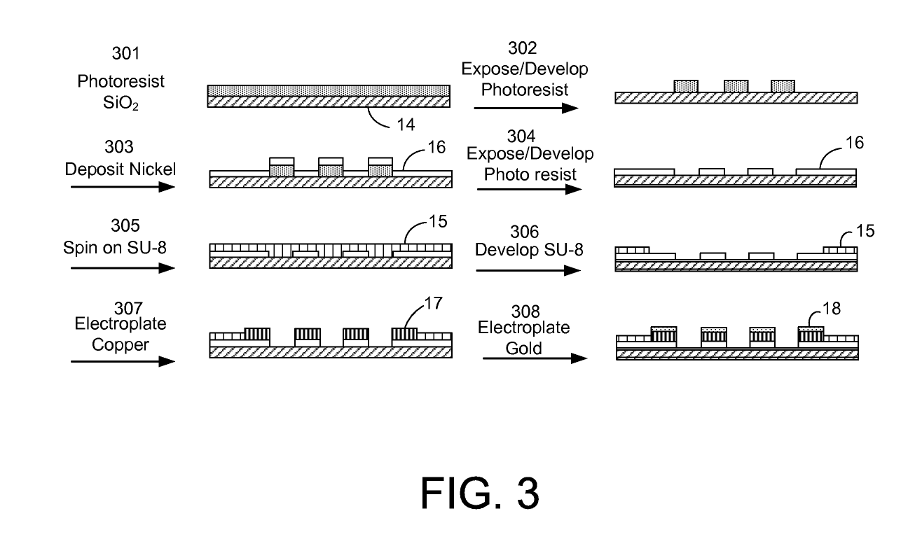

FIG. 3 schematically shows an example micro fabrication process 300, which can be used to fabricate probe 200 beginning with, for example, a fused silica substrate 14. Process 300 may include coating the fused silica substrate with photoresist (301), exposing and developing the photoresist to form a pattern of openings which correspond to the locations for forming line conductors 11a, 11b, 12a, and 12b, conductive paths 19 and terminals 20 on the fused silica substrate (302), and depositing a layer of nickel 16 in the openings (303). Process 300 may further include removing the residual photoresist on fused silica substrate 14 (304) and coating the deposited layer of nickel 16 with an insulating polymer material layer (e.g., SU-8 layer 15) (305), and exposing and developing the SU-8 layer 15 to form openings corresponding to the locations of line conductors 11a, 11b, 12a, and 12b over deposited nickel layer (306). Process 200 then may include electroplating copper 17 on top of nickel layer 16 in the openings (307) and further electroplating gold 18 on top of the electroplated copper 17 (308) to complete the stack of metals (e.g., Ni 16 /Cu 17 /Au 18) forming line conductors 11a, 11b, 12a, and 12b (as shown for example in FIG. 2B). While example probe 300 is described as having line conductors 11a, 11b, 12a, and 12b formed as a stack of nickel, copper and gold metals, it will be understood that line conductors 11a, 11b, 12a, and 12b may be formed using other metals, other combinations of metals, or other conductive materials.

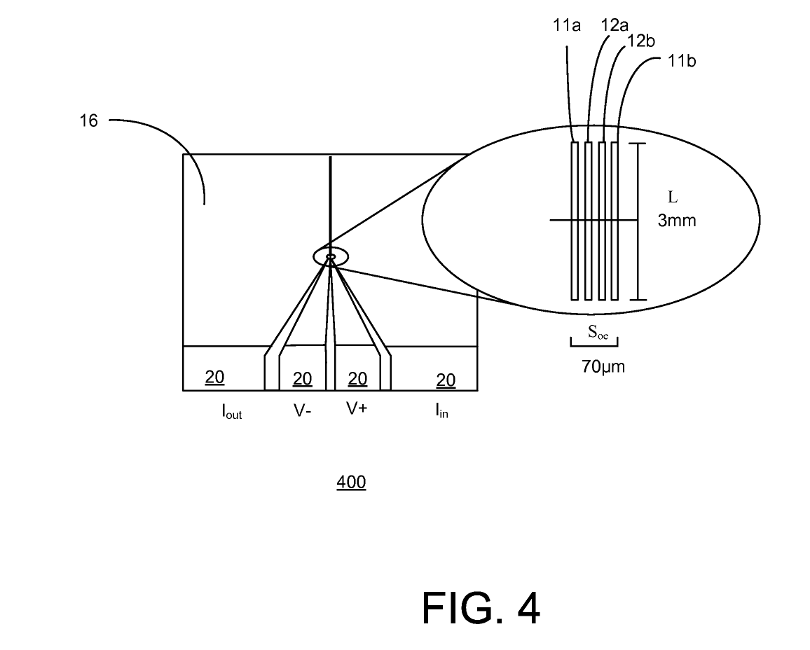

As noted previously, the dimensions of line conductors 11a, 11b, 12a, and 12b in the four-line probes described herein may be chosen to make electrical contact over large or macroscopic areas of the surface of the material under test so that effects of structural or compositional variations in the surface of the material under test are smoothed out during electrical impedance measurements. For a demonstration of the capabilities of using line conductors 11a, 11b, 12a, and 12b for electrical impedance measurements of diverse materials, a probe 400 (FIG. 4) was fabricated using process 300. Probe 400 was designed for electrical impedance measurements of lithium-ion battery electrode (cathode) material (e.g., sample 30). The lithium-ion battery electrode (cathode) material sample was obtained in the form of active battery cathode material (e.g., material layer 31) supported on an aluminum backing layer (e.g., current collector layer 32). Consideration was given to the characteristics of the battery cathode material in the design of probe 400. The lithium-ion battery cathode material (e.g., layer 31 in sample 30) may typically have a conductivity ranging from 10-500 mS/cm (depending on the ingredient active material used), a thickness of 20-100 μm (typically 70 μm) on a metal current collector (e.g., layer 32 in sample 30), and a surface roughness of 5 μm (e.g., of surface 33 in sample 30). The metal current collector, may for example, be an aluminum current collector, a copper metal current collector, a metal alloy current collector, and/or so forth. The surface roughness of the battery cathode material was taken into account to select the widths and lengths of line conductors 11a, 11b, 12a, and 12b in probe 400. In the demonstration probe 400, line conductors 11a, 11b, 12a, and 12b were empirically designed to be 10 μm wide and 3 mm long to ensure that line conductors 11a, 11b, 12a, and 12b had large contact areas and made even and reproducible contact with the battery electrode material under test. While probe 400 is described herein, for example, in the context of testing lithium-ion battery cathode material, it will be understood that the battery electrode material under test can be another type of battery electrode material (e.g., a composite electrode material of a nickel-graphite or, nickel-cadmium or other battery type).

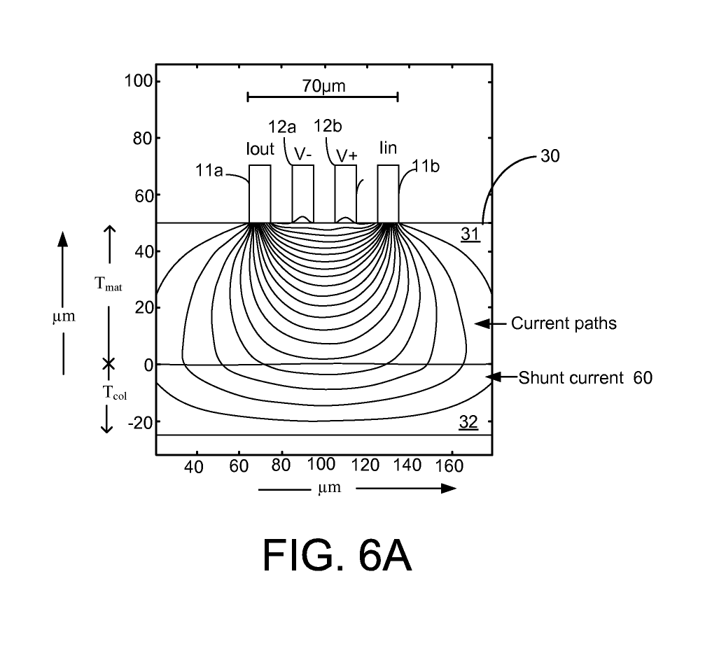

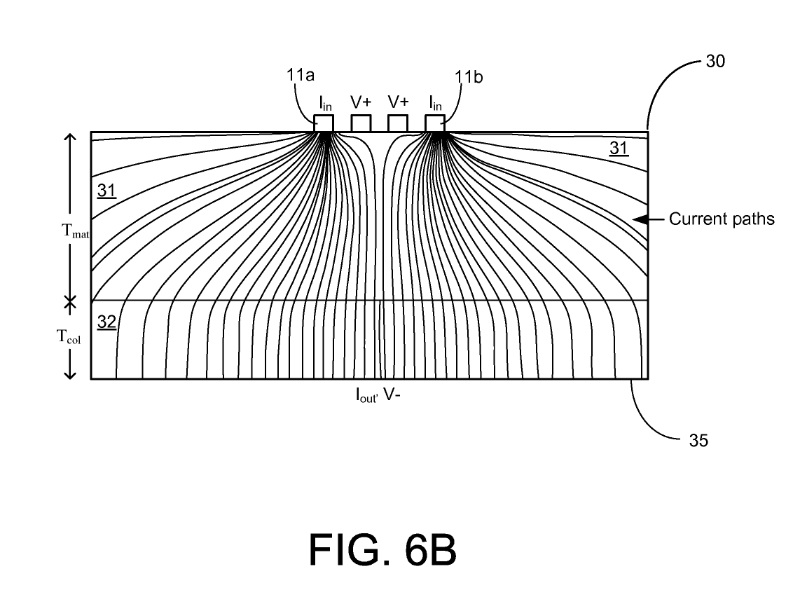

Another consideration in the design of probe 400, relates to the separation or distance between an outermost pair of the line conductors (e.g., 11a and 11b) that is used to inject or establish current flow through sample 30 during electrical impedance measurements. The separation or distance between the outermost pair of line conductors 11a and 11b may be represented as the outer edge-to-outer edge separation Sₒₑ or the inner edge-to-inner edge separation Sᵢₑ as shown in FIGS. 1A and 1B. The separation or distance between the outermost pair of line conductors 11a and 11b may control an amount of shunt current flowing through the aluminum current collector (e.g., layer 32 in sample 30) during electrical impedance measurements using probe 400. A finite element simulation program (e.g., COMSOL multiphysics) was used to simulate current flows through material layer 31 and current collector layer 32 with a thickness of about in sample 30 for varying separations between the outer pair line conductors (e.g., 11a and 11b). For the current flow simulations, material layer 31 in sample 30 had a thickness Tₘₐₜ of about 50 μm and collect current layer 32 had a thickness T_{col} of about 20 μm (for a total sample 30 thickness of about 70 μm). The current flow simulations in two dimensions were representative of current flow in the three dimensional volume of sample 30 because of the symmetry afforded by having length L>>width w for line conductors 11a, 11b, 12a, and 12b in probe 400. FIG. 6A shows an example of such a simulation of current flows in sample 30 for an example separation between the outer pair line conductors Sₒₑ=70 μm (Sᵢₑ=50 μm). From the simulations, it was deduced that there is an optimal distance between the outer pair line conductors (e.g., 11a and 11b) in probe 400. If the outer line conductors are too far apart than the optimal distance, shunt current 60 through current collector layer 32 of sample 30 may increase and the conductivity measurements of layer 31 based on the total current injected by probe 400 in sample 30 may be erroneous. However, if the outer line conductors are too close, current flow may be excessively concentrated near surface 33 of sample 30 and may not sample the entire volume of material layer 31. From the COMSOL multiphysics simulations it was determined that a separation distance between the outer pair line conductors (e.g., 11a and 11b) in probe 400, which is on the same order as the thickness of the battery cathode materials provides an even current distribution in the volume of material layer 31 while maintaining a minimum shunt current through current collector layer 32. A separation distance (e.g., Sₒₑ or Sᵢₑ) between the outer pair line conductors (e.g., 11a and 11b) in probe 400, which is, for example, within about ±25% of sample 30 or material layer 31 thickness may provide an even current distribution to evenly sample the volume of material layer 31

Accordingly, as shown in FIG. 4, demonstration probe 400 was fabricated with Sₒₑ=70 μm (Sᵢₑ=50 μm) for electrical impedance measurements of battery cathode materials that have a thickness in the range of 20 μm to 120 μm (typically 70 μm).

Probe 400 as shown in FIG. 4 may be a planar device on an insulating wafer that is almost entirely covered by an insulating polymer coating 16. Only two areas may be are exposed. As can be seen in FIG. 4, one exposed area is a 70 μm×3 mm window in insulating polymer coating 16 where line conductors 11a, 11b, 12a, and 12b are exposed (shown in exploded view). The second exposed area may include four pads of exposed nickel (terminals 20) that may be used to connect probe 400 to a current source and electronic measurement equipment (not shown).

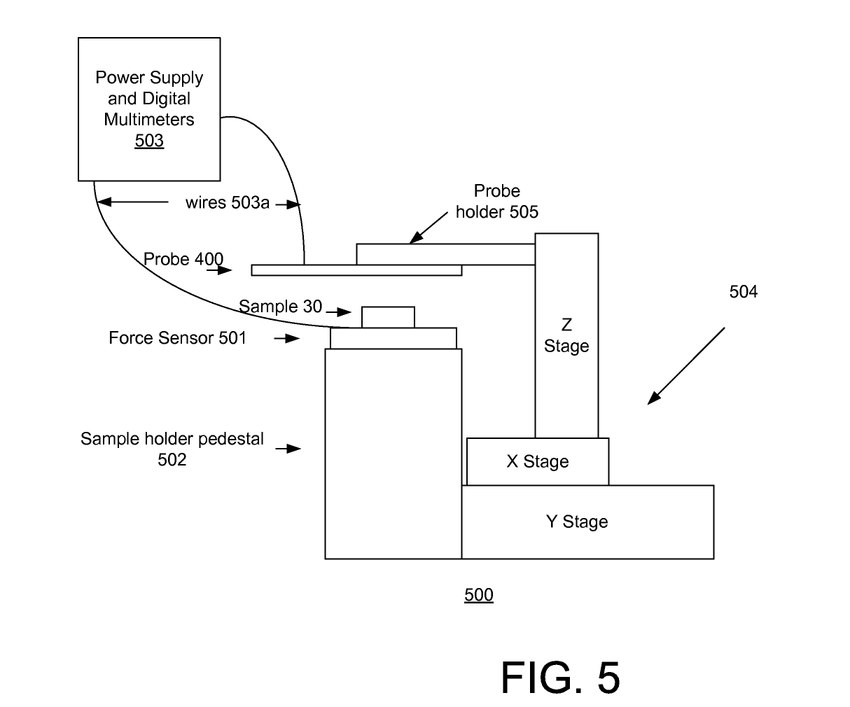

FIG. 5 shows an example probe station 500 which may be used to measure electrical impedances under controlled contact pressure at controlled positions on the surface of sample 30 using probe 400. In example probe station 500, sample 30 may be placed on a sample holder pedestal 502 for the electrical impedance measurements. Probe station 500 may include a probe holder 505 on which probe 400 is mounted. Probe holder 505 may be attached to an X-Y-Z stage 504, which may allow controlled movement of probe holder 505/probe 400 in X, Y and Z directions. X-Y-Z stage 504 may be precise and may have a location or position repeatability, for example, with a 30 nm resolution and a less than 2 μm positional accuracy.

In probe station 500, electrical measurement equipment (e.g., power supply and digital multimeters 503) may be connected to terminals 20 of probe 400 and to sample 30, for example, via wires 503a. X-Y-Z stage 504, which may be automated or manual, may allow probe 400 to be brought in contact with sample 30 under controlled pressure (e.g., 0 to 100 kPa) at different measurement locations. A force sensor 501 may be included in sample holder pedestal 502 to measure the pressure with which probe 400 is applied to sample 30.

Example probe station 500 may be configured to make electrical impedance measurements in one of two modes. A first “lateral” or “standard” mode of measurement, as shown in FIG. 6A, may involve using the outer pair of line conductors (e.g., 11a and 11b) in probe 400 to establish a current flow (Iₒᵤₜ=Iᵢₙ=I_{outer pair}) through sample 30, and using the inner pair of line conductors (e.g., 12a and 12b) to measure a voltage (V+−V−=V_{inner pair}) developed across the inner pair of line conductors (e.g., 12a and 12b) in contact with sample 30. A second “orthogonal” mode of measurement (shown in FIG. 6B) may involve using the outer pair of line conductors (e.g., 11a and 11b) in probe 400 to inject current flow (Iᵢₙ) orthogonally across sample 30 to current collector layer 32, and measuring a voltage ((V+)−(V−)) developed orthogonally between the inner pair of line conductors (e.g., 12a and 12b) and a surface (e.g., a bottom surface 35) of current collector layer 32.

The lateral or standard mode of measurement may yield a first apparent resistance (e.g., R_{app-std}=(V_{inner pair})/(I_{outer pair})) for sample 30. Similarly the orthogonal mode measurement may yield a second apparent resistance Rₐₚₚ₋ₒᵣₜₕ for sample 30 as the ratio of measured voltage and current. In accordance with the principles of the present disclosure, the first apparent resistance R_{app-std}, may be converted to an electrical impedance parameter (i.e. a bulk conductivity or resistivity value) for material 31 in sample 30 by applying an empirically determined geometrical correction factor “S0” to account for the shunt current 60 flows extending through current collector layer 32 during the lateral mode measurement (FIG. 6A). Further, using the bulk conductivity value, the second apparent resistance Rₐₚₚ₋ₒᵣₜₕ may be converted to a value for a contact resistance (“collector layer contact resistance”) between material layer 31 and the current collector layer 32. In accordance with the principles of the present disclosure, determining the collector layer contact resistance value may involve applying two empirically determined geometrical correction factors “S1” and “S2” to account for the shunt current flows extending into the current collector layer 32 during the orthogonal mode measurement.

Because of the geometrical differences, traditional four-point probe equations are not directly applicable to a four-line probe (e.g., probe 400), especially when the current collector layer 32 is still attached to material layer 31. To account for these differences, a COMSOL two dimensional numerical model may be merged with the experimental data using geometrical shape factors So, S1 and S2, in accordance with the principles of the disclosure herein. These shape factors may be almost exclusively a function of sample 30 thickness and probe line conductor spacing (e.g., d and S). The geometrical shape factors So, S1 and S2 may be developed as an extension of Ohm's law.

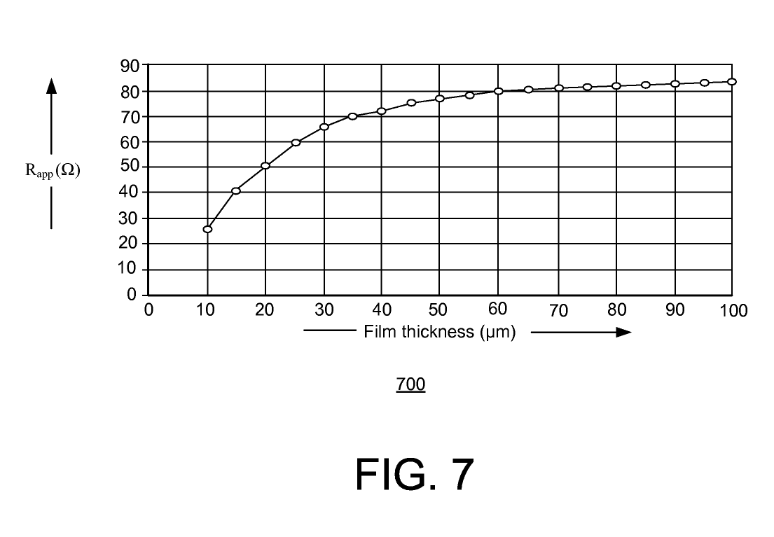

For simple geometries (i.e. where current collector layer 32 is not attached to material layer 31), an expression which relates resistance, geometry, and resistivity of material layer 31 under Ohm's law can be written as ρ=R*L/A. However, this expression may be modified for the case where when current collector layer 32 is still attached to material layer 31 (e.g., as in the standard and orthogonal modes of measurement shown in FIGS. 6A and 6B, respectively) by recognizing that the amount of current passing through current collector 32 during the measurements is a function of material layer 31 thickness and the collector layer contact resistance. Numerical modeling (e.g., COMSOL simulations) may be used to estimate the effect of probe geometrical factors and sample geometrical factors on the measured values of electrical impedance of sample 30 using probe 400. FIG. 7 shows, for example, a simulated plot 700 of the apparent resistance R_{app-std} of material layer 31 as a function of material layer 31 thickness, which was obtained by COMSOL simulation using geometrical factors 10 μm spacing for line conductors 11a, 11b, 12a and 12b in probe 400.

In accordance with the principles of the present disclosure, the bulk conductivity σ_{b} of material layer 31 may be numerically modeled by the equation

σ_{b}=1/ρ=1/(R_{app-std.}*S0),

where S0 is the empirically determined geometric shape factor. Similarly, the contact resistance 1/σ_{contact} (“collector layer contact resistance”) between material layer 31 and current collector layer 32 may be numerically modeled by the equation

1/σ_{contact}=S2*(Rₐₚₚ₋ₒᵣₜₕ−Rₐₚₚ−_{std.}*S0/S1),

where S1 and S2 are the empirically determined geometric shape factors.

The geometric shape factor S0 may be determined from the numerical COMSOL model by assigning reasonable values for the contact resistance, surface roughness, bulk conductivity, and the exact values of the probe line conductor spacing and material layer 31 thickness. The geometric shape factors S1 and S2 may be determined in a similar way for the orthogonal measurements by assigning reasonable values for the contact resistance, surface roughness, bulk conductivity, and the exact values of the probe line conductor and material layer 31 thickness. In the modeling, bulk conductivity may then be varied until the Rₐₚₚ of the model matches that the measured Rₐₚₚ.

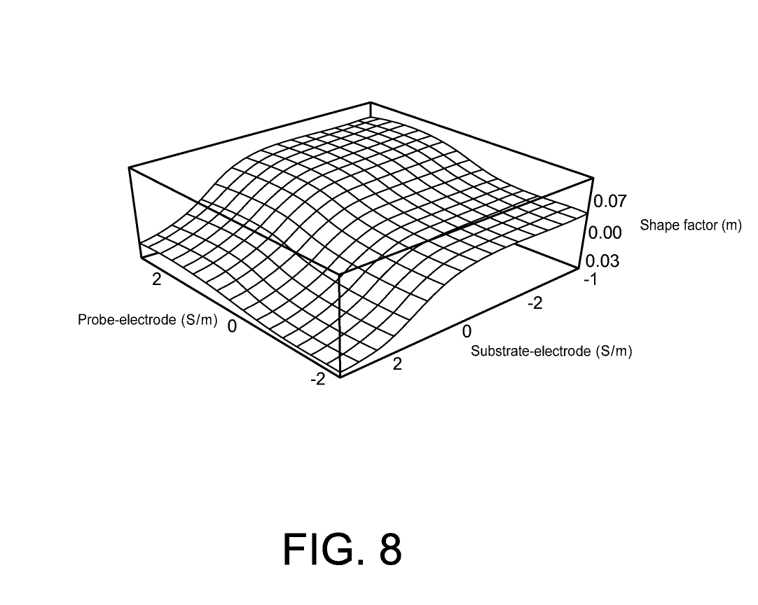

The geometric shape factors S0, S1 and S2 applied to the measured apparent resistances may account for geometric complexities and irregular current paths through more conductive materials (in sample 30). In numerical modeling studies of measurements on battery electrode materials, the geometric shape factors (e.g., S0) were found to be a strong function of probe line conductor spacing and material layer 31 thickness. However, the geometric shape factors (e.g., S0) were found to be only a slight function of bulk conductivity (σ_{b}) of the battery electrode materials and the contact resistance (“probe contact resistance”) between the probe and material layer 31. FIG. 8 shows a logarithmic plot of the qualitative dependence of the geometric shape factor S0 on probe contact resistance and collector layer contact resistance. As seen from FIG. 8, a change of five orders of magnitude in the probe contact resistance has a negligible effect on S0 compared with, for example, other inherent experimental error in the electrical impedance measurements. Similarly, the bulk conductivity σ_{b} of material layer 31 has negligible effect on S0. For σ_{b} in a range from 8 to 240 mS/cm, the shape factor S0 varies only by about ±1.5%. In contrast, a change of six orders of magnitude in the collector layer contact resistance changes the shape factor by about 26%.

With the foregoing understanding of the qualitative dependencies of the shape factors, a table of shape factors may be created in which the shape factors are approximated only as a function of collector layer contact resistance and probe geometry (i.e., the width dimensions and spacing of line conductors 11a, 11b, 12a and 12b) ignoring the slight dependencies on probe contact resistance and the bulk conductivity σ_{b}. Further, for a fixed probe geometry, a single look-up table of geometric shape correction factors (e.g., as a function of collector layer contact resistance) may be set up for use in converting measured Rₐₚₚ values to electrical impedance parameters (e.g., conductivity permittivity, etc.). Use of the look-up table may only require that the apparent resistance Rₐₚₚ is known experimentally, and that the collector contact layer resistance be known within an order of magnitude (because of the weak or slight dependence of geometric shape correction factors on the probe contact resistance). Alternatively or additionally, each shape factor may be approximated by simplified mathematical equations to accomplish the same functionality as the look-up table, i.e. to enable a user to quickly determine a needed shape factor.

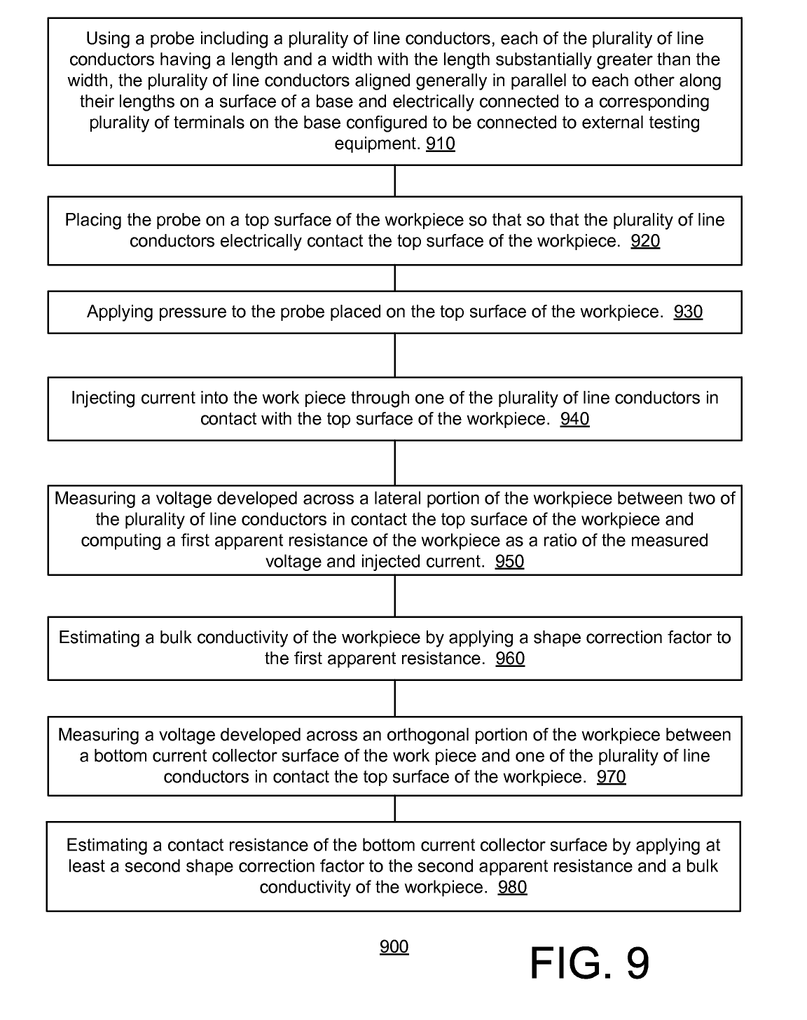

FIG. 9 a flow chart illustrating an example method 900 for determining electrical impedance parameters of a workpiece, in accordance with the principles of the disclosure herein. Method 900 includes using a probe including a plurality of line conductors, each of the plurality of line conductors having a length and a width with the length substantially greater than the width, the plurality of line conductors aligned generally in parallel to each other along their lengths on a surface of a base and electrically connected to a corresponding plurality of terminals on the base configured to be connected to external testing equipment (910). Method 900 further includes placing the probe on a surface of the workpiece so that so that the plurality of line conductors electrically contact the surface of the workpiece (920) and may optionally include applying pressure to the probe placed on the surface of the workpiece (930).

Method 900 further includes injecting current into the workpiece through one of the plurality of line conductors in electrical contact with the surface of the workpiece (940), measuring a voltage developed across a lateral portion of the workpiece between two of the plurality of line conductors in contact with the surface of the workpiece and computing a first apparent resistance of the workpiece as a ratio of the measured voltage and injected current (950), and estimating a bulk conductivity of the workpiece by applying a shape correction factor to the first apparent resistance (960).

Method 900 may also include measuring a voltage developed across a portion of the workpiece between a current collector surface of the work piece and one of the plurality of line conductors in contact with the surface of the workpiece (970) and estimating a contact resistance of the current collector surface by applying at least a second shape correction factor to the second apparent resistance and a bulk conductivity of the workpiece (980).

The figures of the different embodiments described in the foregoing may not be to scale, and as such are not intended to limit the possible variations in the layout or design of the corresponding structures. While certain features of the described implementations of devices and methods have been illustrated as described herein, many modifications, substitutions, changes and equivalents will now occur to those skilled in the art. For example, while the electrical impedance of a material under test may have been described herein with reference to the devices and methods, for example, of FIGS. 1-9, as being a “pure” resistance R, it will be understood that the devices and methods can be used to determine complex electrical impedances, which may include, for example, effects of the phase response of the material under test and/or its dielectric properties. The contact resistances described herein with reference to the devices and methods of FIGS. 1-9 may be contact impedances that include, for example, in the case of electrolytic materials, a Warburg element or a constant phase element.

Further, for example, the devices and methods of FIGS. 1-9 may be used to measure electrical impedance of battery electrode material (or other material or workpiece) in both dry and wet states. In a wet state of a battery electrode material under real-world operating conditions, a non-conducting liquid or an ion-containing liquid electrolyte may be present in the vicinity of or in contact of the material. The device of methods of FIGS. 1-9 may be used to measure electrical impedances of the battery electrode material under conditions which simulate real-world operating conditions. For example, sample holder pedestal 502 of probe station 500 (described earlier with reference to FIG. 5) may be modified to allow addition of a quantity of a non-conducting or ion-conducting liquid electrolyte to a workpiece (e.g., sample 30) during the electrical impedance measurements (described, for example, with reference to FIG. 9). The quantity of liquid added during an electrical impedance measurement may fill pore spaces within material layer 31 of sample 30 and may also fill any gaps between sample 30 and probe 400 to simulate real-world operating conditions of a battery electrode. For a characterization of the battery electrode material (e.g. material layer 31) method 900 of FIG. 9 may include measuring the electrical impedance parameters of sample 30 in both a dry state (without liquid present) and in a wet state after addition of the a non-conducting or ion-conducting liquid electrolyte to sample 30 to simulate real-world operating conditions of the battery electrode.

It is, therefore, to be understood that the appended claims are intended to cover all modifications and changes as fall within the true spirit of the present disclosure.

1. A probe, comprising:
a base; and
a plurality of line conductors aligned substantially in parallel to each other on a surface of the base and electrically connected to a corresponding plurality of terminals on the base, the plurality of line conductors including at least four line conductors, the base configured to be placed over a surface of a workpiece so that the plurality of line conductors contact the surface of the workpiece, and the corresponding plurality of terminals configured to be connected to external testing equipment.

2. The probe of claim 1 wherein the base includes a fused silica substrate and an insulating polymer coating.

3. The probe of claim 1 wherein the plurality of line conductors includes lithographically-patterned metal lines deposited on the non-conducting base.

4. The probe of claim 1 wherein each of the plurality of line conductors has a length and a width along the surface of the non-conducting base and protrudes vertically to a height from the surface of the base to a line conductor top that contacts the surface of the workpiece when the base is placed over the surface of the workpiece, wherein the length the plurality of line conductors is substantially greater than the width of the plurality of line conductors.

5. The probe of claim 4 wherein the plurality of line conductors have widths on the order of microns.

6. The probe of claim 1 wherein each of the plurality of line conductors has a length of about 3 mm and a width of about 10 μm, and the plurality of line conductors has an inter-line spacing of about 10 μm.

7. A probe station comprising:
a workpiece holder configured to hold a workpiece; and
a probe including a plurality of line conductors disposed substantially in parallel to each other on a surface of a base and electrically connected to a corresponding plurality of terminals on the configured to be connected to external testing equipment; and
a probe holder configured to bring the probe in contact with a surface of workpiece so that the plurality of line conductors contact the surface of the workpiece.

8. The probe station of claim 7 further comprising a pressure sensor configured to measure a pressure with which the probe holder brings the probe in contact with the surface of workpiece.

9. The probe station of claim 7, wherein the external test equipment includes an ammeter configured to measure a current injected into the workpiece through one of the plurality of line conductors in contact with the surface of the workpiece and a voltmeter configured to measure a voltage developed across a portion of the workpiece.

10. The probe station of claim 7, wherein the external test equipment is configured to measure a voltage developed across a lateral portion of the workpiece between two of the plurality of line conductors in contact the surface of the workpiece.

11. The probe station of claim 7, wherein the external test equipment is configured to measure a voltage developed across a portion of the workpiece between a current collector surface of the workpiece and one of the plurality of line conductors in contact the surface of the workpiece.

12. The probe station of claim 7, further comprising an analysis unit configured to:
compute a first apparent resistance based on a measurement of a voltage developed across a lateral portion of the workpiece between two of the plurality of line conductors in contact the surface of the workpiece; and
estimate a bulk conductivity of the workpiece by applying at least a first shape correction factor to the first apparent resistance.

13. The probe station of claim 12, wherein the analysis unit is further configured to:
compute a second apparent resistance based on a measurement of a voltage developed across a portion of the workpiece between a current collector surface of the workpiece and one of the plurality of line conductors in contact the surface of the workpiece; and
estimate a contact resistance between portions of the workpiece by applying at least a second shape correction factor to the second apparent resistance and the bulk conductivity.

14. The probe station of claim 7, wherein the workpiece holder is configured to include a liquid in contact with the workpiece.

15. A method comprising:
using a probe including a plurality of line conductors, each of the plurality of line conductors having a length and a width with the length substantially greater than the width, the plurality of line conductors aligned generally in parallel to each other along their lengths on a surface of a base and electrically connected to a corresponding plurality of terminals on the base configured to be connected to external testing equipment; and
placing the probe on a surface of the workpiece so that so that the plurality of line conductors electrically contact the surface of the workpiece.

16. The method of claim 15, further comprising applying pressure to the probe placed on the surface of the workpiece.

17. The method of claim 15 further comprising injecting current into the work piece through one of the plurality of line conductors in contact with the surface of the workpiece.

18. The method of claim 17 further comprising measuring a voltage developed across a lateral portion of the workpiece between two of the plurality of line conductors in contact with the surface of the workpiece and computing a first apparent resistance of the workpiece as a ratio of the measured voltage and injected current.

19. The method of claim 18 further comprising estimating a bulk conductivity of the workpiece by applying a shape correction factor to the first apparent resistance.

20. The method of claim 17 further comprising measuring a voltage developed across a portion of the workpiece between a current collector surface of the work piece and one of the plurality of line conductors in contact with the surface of the workpiece.

21. The method of claim 20 further comprising estimating a contact resistance of the current collector surface by applying at least a second shape correction factor to the second apparent resistance and a bulk conductivity of the workpiece.

22. The method of claim 15 further comprising placing a liquid in contact with the workpiece.
